(19) United States
(12) Patent Application Publication
(10) Pub. No.: US 2021/0360099 A1
(43) Pub. Date: Nov. 18, 2021

(54) FOLDABLE DISPLAY

(71) Applicant: WUHAN CHINA STAR OPTOELECTRONICS SEMICONDUCTOR DISPLAY TECHNOLOGY CO., LTD., Wuhan, Hubei (CN)

(72) Inventor: Weiguo YOU, Wuhan, Hubei (CN)

(21) Appl. No.: 16/612,298

(22) PCT Filed: May 9, 2019
(86) PCT No.: PCT/CN2019/086140

§ 371 Date: Nov. 8, 2019

(30) Foreign Application Priority Data
Apr. 22, 2019 (CN) 201910321613.8

(51) Int. Cl. H04M 1/02; H03K 17/96; G01B 7/16

(52) U.S. Cl. CPC H04M 1/0268; G01B 7/22; G01B 7/18; H03K 17/964

(57) ABSTRACT

A foldable display including a bendable region, the bendable region comprising a first surface functioning as a display surface of the display and a second surface disposed opposite to the first surface. The foldable display has an unfolded state and a folded state. The foldable display includes a state detecting unit disposed in the bendable region for detecting a deformation state of a surface of the bendable region and generating an electrical signal indicating a corresponding deformed state.

### CROSS REFERENCE TO RELATED APPLICATION

This application claims the priority of International Application No. PCT/CN2019/086140, filed on 2019 May 9, which claims priority to Chinese Application No. 201910321613.8, filed on 2019 Apr. 22. The entire disclosures of each of the above applications are incorporated herein by reference.

### BACKGROUND OF INVENTION

### Field of Invention

The present invention relates to the field of display technologies, and in particular, to a foldable display.

### Description of Prior Art

With continuous development of display technology, portable display devices, such as mobile phones and tablet computers, can be seen everywhere. A large-area display can enhance user visual experience, but making displays larger makes display devices inconvenient to carry, so the foldable display devices came into being.

In prior art, a foldable display device typically has a bending axis extending through a bending region of the display device, the foldable display device is foldable about the bending axis of the bending region. When it is required to adjust the display condition and the touch function of the display panel according to the folded state of the foldable display device, it is necessary to detect a state of the foldable display device.

### Technical Problem

Detection methods in the prior art include setting a magnetic switch or a light-sensing switch near the camera of the display panel, and when the display panel is folded, the magnetic switch or the light-sensing switch is triggered to close the screen. Both of them judge the folding state of the display panel according the external state, which is easily interfered by external factors and leads to a false positive.

### SUMMARY OF INVENTION

The present application provides a foldable display, which can detect the bending state of the display without relying on external signals, thereby avoid misjudgment.

In order to solve the above problems, the present application provides a foldable display comprising:

a bendable region, the bendable region comprising a first surface functioning as a display surface of the display and a second surface disposed opposite to the first surface;

wherein, the foldable display has an unfolded state, a folded state, and a half-folded state;

wherein the foldable display includes a state detecting unit for detecting a current state of the foldable display, the state detecting unit includes a pressure sensor disposed in the bendable region for detecting a deformation state of a surface of the bendable region and generating an electrical signal indicating a corresponding deformed state.

According to one aspect of the application, wherein in the unfolded state, the first surface and the second surface are not deformed;

wherein in the folded state, the first surface and the second surface are deformed, and an included angle between portions of the display on both sides of the bendable region is 0 degrees; and

wherein in the half-folded state, the first surface and the second surface are deformed, and the included angle between the portions of the display on both sides of the bendable region is greater than 0 degrees and less than 180 degrees.

According to one aspect of the application, wherein the state detecting unit further includes a processor configured to receive and identify an electrical signal transmitted by the pressure sensor, the processor is used for obtaining the angle between the portions of the display on both sides of the bendable region according to the electrical signal and indicating a state in which the foldable display is in.

According to one aspect of the application, wherein the display surface of the foldable display includes a visible area and a non-visible area located beside or around the visible area, and the pressure sensor is located on the non-visible area of the display surface or on a non-display surface of the foldable display.

According to one aspect of the application, wherein the display surface of the foldable display includes a visible area and a non-visible area located beside or around the visible area, and the pressure sensor is located in the visible area of the display surface of the foldable display and the pressure sensor is made of transparent material.

According to one aspect of the application, wherein the pressure sensor is a resistive pressure sensor.

According to one aspect of the application, wherein the resistive pressure sensor includes a first deformation resistor.

According to one aspect of the application, wherein the resistive pressure sensor further includes a first resistor, a second resistor and a third resistor, the first resistor, the second resistor and the third resistor are balanced resistors each having a constant resistance, and the constant resistance is equal to a resistance of the first deformation resistor when the first deformation resistor is not deformed;

wherein the first resistor, the second resistor, the third resistor and the first deformation resistor constitute a first Wheatstone balance bridge.

According to one aspect of the application, wherein the first Wheatstone balance bridge is located in the non-visible area of the display surface of the foldable display, and a geometric center of the first deformation resistor overlaps with a bending axis of the bendable region.

According to one aspect of the application, wherein the resistive pressure sensor further includes a second deformation resistor, the second deformation resistor is located in the non-visible area of the display surface of the foldable display and corresponding to a position of the first deformation resistor;

wherein the resistive pressure sensor further includes a fourth resistor, a fifth resistor, and a sixth resistor, the fourth resistor, the fifth resistor and the sixth resistor are balance resistors each having a constant resistance, and the constant resistance of each of the fourth, fifth and sixth resistors is equal to a resistance of the second deformation resistor when the second deformation resistor is not deformed;

wherein the fourth resistor, the fifth resistor, the sixth resistor and the second deformation resistor constitute a second Wheatstone balanced bridge.

According to one aspect of the application, wherein the first Wheatstone balance bridge is located on the non-display surface of the foldable display, a geometric center of the first deformation resistor overlaps with a bending axis of the bendable region, and a projection length of the first deformation resistor along the bending axis direction of the bendable region is equal to a length of the bending axis of the bendable region.

According to one aspect of the application, wherein the first Wheatstone balance bridge is located on a display surface of the foldable display and the resistors constituting the first Wheatstone balanced bridge each are made of transparent material, a geometric center of the first deformation resistor overlaps with a bending axis of the bendable region, a projection length of the first deformation resistor along the bending axis direction of the bendable region is equal to a length of the bending axis of the bendable region.

According to one aspect of the application, wherein when the foldable display is in the unfolded state, the first deformation resistor has a maximum resistance value and the electrical signal detected by the processor is a maximum voltage signal;

wherein when the foldable display is in the folded state, the first deformation resistor has a minimum resistance value and the electrical signal detected by the processor is a minimum voltage signal; and

wherein the current state of position of the foldable display can be determined by comparing the magnitude of the voltage signal detected by the processor.

According to one aspect of the application, wherein when the foldable display is in the half-folded state, a resistance value of the first deformation resistor is between a maximum resistance and a minimum resistance and the resistance value of the first deformation resistor is negatively correlated to the bending angle of the foldable display;

wherein the current folding angle of the foldable display can be determined by comparing the magnitude of the voltage signal detected by the processor.

According to one aspect of the application, wherein the pressure sensor is a capacitive pressure sensor.

According to one aspect of the application, wherein the capacitive pressure sensor includes a deformation capacitance.

According to one aspect of the application, wherein a geometric center of the deformation capacitor overlaps with a bending axis of the bendable region, two plates of the deformation capacitor are conductive layers printed on both sides of an organic elastic insulator respectively.

According to one aspect of the application, wherein when the foldable display is in the unfolded state, the deformation capacitor has a minimum capacitance value, and the electrical signal detected by the processor is a minimum voltage signal;

wherein when the foldable display is in the folded state, the deformation capacitor has a maximum capacitance value, and the electrical signal detected by the processor is a maximum voltage signal; and

wherein the current state of position of the foldable display can be determined by comparing the magnitude of the voltage signal detected by the processor.

According to one aspect of the application, wherein when the foldable display is in the half-folded state, a capacitance value of the first deformation capacitance is between the maximum capacitance and the minimum capacitance and the capacitance value of the first deformation capacitance is negatively correlated to the bending angle of the foldable display;

wherein the current folding angle of the foldable display can be determined by comparing the magnitude of the voltage signal detected by the processor.

According to one aspect of the application, wherein the pressure sensor is a piezoelectric pressure sensor.

According to one aspect of the application, wherein the piezoelectric pressure sensor includes a piezoelectric film.

According to one aspect of the application, wherein the piezoelectric film includes a first surface, a second surface, a first electrode electrically connected to the first surface of the piezoelectric film and a second electrode electrically connected to the second surface of the piezoelectric film, the first electrode is in close contact with the bendable region and the second electrode is away from the bendable region.

According to one aspect of the application, wherein when the foldable display is in the unfolded state, the first surface and the second surface are not deformed, and the surface stress is zero, a minimum voltage difference exits between the first electrode and the second electrode, wherein the electrical signal detected by the processor is a minimum piezoelectric signal;

wherein when the foldable display is in the folded state, a resultant force of the first surface is in a direction of the bending radius, perpendicular to the bending axis of the bendable region and pointing to the outside of a bending arc;

wherein an absolute value of a resultant force generated by a compressive stress of the second surface is greater than an absolute value of the resultant force generated by a compressive stress of the first surface, a direction of the resultant force generated by the second surface is opposite to the direction of the resultant force generated by the first surface;

wherein a pressure applied to a surface of the piezoelectric film is a sum of the compressive stresses of the first surface and the compressive stresses of the second surface, a direction of the pressure applied to a surface of the piezoelectric film is consistent with the direction of the compressive stress of the second surface;

wherein electric charges inside the piezoelectric film is shifted by the pressure, positive and negative charges are collected on the first surface and the second surface of the piezoelectric film respectively, and the electrical signal detected by the processor is the maximum piezoelectric signal.

According to one aspect of the application, wherein when the foldable display is in the half-folded state, a magnitude of the piezoelectric signal between the first surface and the second surface of the piezoelectric film is between the maximum piezoelectric signal and the minimum piezoelectric signal, a piezoelectric signal of the piezoelectric film is positively correlated with a bending angle of the foldable display;

wherein the current folding angle of the foldable display can be determined by comparing the magnitude of the voltage signal detected by the processor.

### Beneficial Effect

The present application provides a pressure sensor on a bending axis of a bending region of a foldable display, therefore a change of the bending state of the bending axis of the bending region can be converted into a change of an electric signal by the pressure sensor to complete the detection of the bending state of the display screen. This method does not need to rely on external optical signals or magnetic signals and is completely completed by the deformation of the display itself when bending. The foldable display screen of the present application can completely eliminate the interference of external factors on the detection result and greatly improve the accuracy of detection and avoiding misjudgment.

### BRIEF DESCRIPTION OF DRAWINGS

FIG. 1 is a schematic diagram of a display surface of a foldable display in an embodiment of the present application.

FIG. 2 is a schematic diagram of a non-display surface of the foldable display of FIG. 1.

FIG. 3 is a schematic diagram of a foldable display provided with a pressure sensor according to Embodiment 1 of the present application.

FIG. 4 is a schematic structural diagram of the pressure sensor in the foldable display provided with the pressure sensor of FIG. 3.

FIG. 5 is a schematic diagram of a principle of the pressure sensor of FIG. 4.

FIG. 6 is a schematic diagram of a foldable display provided with a pressure sensor according to Embodiment 2 of the present application.

FIG. 7 is a schematic diagram of a foldable display provided with a pressure sensor according to Embodiment 3 of the present application.

FIG. 8 is a schematic diagram of a foldable display provided with a pressure sensor according to Embodiment 4 of the present application.

FIG. 9 is a schematic diagram of a foldable display provided with a pressure sensor according to Embodiment 5 of the present application.

FIG. 10 is a schematic diagram of a foldable display provided with a pressure sensor according to Embodiment 6 of the present application.

FIG. 11 is a schematic diagram of a principle of the pressure sensor of FIG. 10.

FIG. 12 is a schematic diagram of a foldable display provided with a pressure sensor according to Embodiment 7 of the present application.

FIG. 13 is a schematic diagram of a foldable display provided with a pressure sensor according to Embodiment 8 of the present application.

FIG. 14 is a schematic diagram of a principle of the pressure sensor of FIG. 13.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

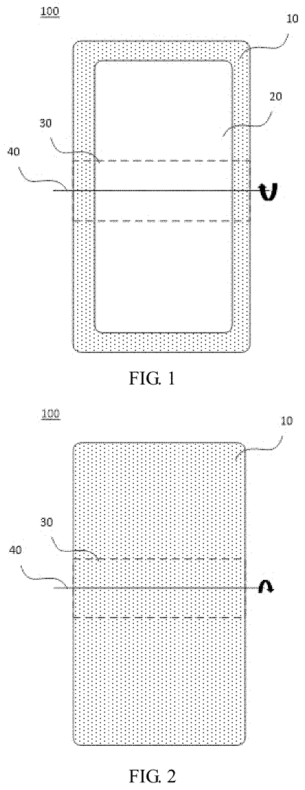

The present application provides a foldable display, which can detect a bending state of the display without relying on external signals, thereby avoiding misjudgment. Referring to FIG. 1 and FIG. 2, FIG. 1 is a schematic diagram of a display surface of a foldable display 100 in an embodiment of the present application, FIG. 2 is a schematic diagram of a non-display surface of the foldable display 100 of FIG. 1. The foldable display 100 includes a bendable region 30, the bendable region 30 has a bending axis 40 parallel to an axis of the foldable display 100, the bendable region 30 comprising a first surface functioning as a display surface of the display and a second surface disposed opposite to the first surface.

The foldable display 100 has an unfolded state and a folded state, in the unfolded state, the first surface and the second surface of the foldable display 100 are not deformed. An included angle between the portions of the display on both sides of the bendable region 30 is 180 degrees. In the folded state, the first surface and the second surface are deformed, and an included angle between portions of the display on both sides of the bendable region 30 is 0 degrees.

The foldable display 100 includes a state detecting unit for detecting a current state of the foldable display 100, the state detecting unit includes a pressure sensor disposed in the bendable region 30 for detecting a deformation state of a surface of the bendable region and generating an electrical signal indicating a corresponding deformed state.

The foldable display 100 also has a half-folded state, in the half-folded state, the first surface and the second surface are deformed, and the included angle between the portions of the display on both sides of the bendable region 30 is greater than 0 degrees and less than 180 degrees.

The state detecting unit further includes a processor 504 configured to receive and identify an electrical signal transmitted by the pressure sensor, the processor is used for obtaining the angle between the portions of the display on both sides of the bendable region 30 according to the electrical signal and indicating a state in which the foldable display 100 is in.

The display surface of the foldable display 100 includes a visible area 20 and a non-visible area 10 located beside or around the visible area 20, and the pressure sensor is located on the non-visible area 10 of the display surface or on a non-display surface of the foldable display 100.

The display surface of the foldable display 100 includes a visible area 20 and a non-visible area 10 located beside or around the visible area 20, and the pressure sensor is located in the visible area 10 of the display surface of the foldable display 100 and the pressure sensor is made of transparent material.

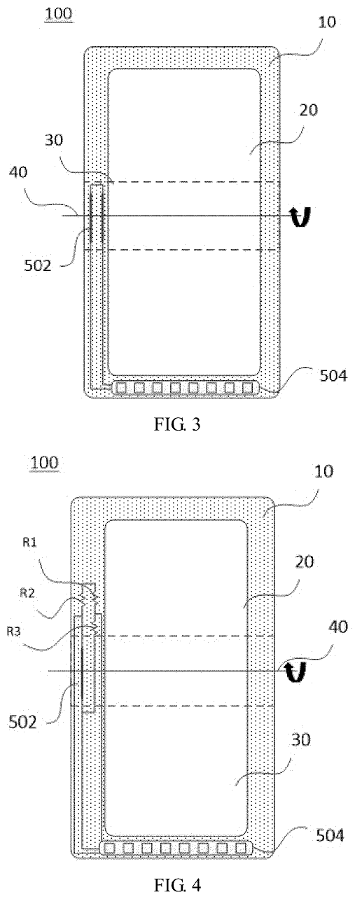

Referring to FIG. 3, according to Embodiment 1 of the present application, the pressure sensor is a resistive pressure sensor. As shown in FIG. 3, the resistive pressure sensor includes a first deformation resistor 502.

Referring to FIG. 4, in Embodiment 1, the resistive pressure sensor further includes a first resistor R1, a second resistor R2 and a third resistor R3. The first resistor R1, the second resistor R2 and the third resistor R3 each having a constant resistance, and the constant resistance is equal to a resistance of the first deformation resistor 502 when the first deformation resistor 502 is not deformed. The first resistor R1, the second resistor R2 and the third resistor R3 and the first deformation resistor 502 constitute a first Wheatstone balance bridge.

A principle of the Wheatstone balanced bridge is shown in FIG. 5.

Wherein the first Wheatstone balance bridge is located in the non-visible area 10 of the display surface of the foldable display 100, and a geometric center of the first deformation resistor 502 overlaps with a bending axis 40 of the bendable region.

When the foldable display 100 is in the unfolded state, the first deformation resistor 502 has a maximum resistance value and the electrical signal detected by the processor 504 is a maximum voltage signal. When the foldable display 100 is in the folded state, the first deformation resistor 502 has a minimum resistance value and the electrical signal detected by the processor 504 is a minimum voltage signal. The current state of position of the foldable display 100 can be determined by comparing the magnitude of the voltage signal detected by the processor 504.

When the foldable display 100 is in the half-folded state, a resistance value of the first deformation resistor 502 is between a maximum resistance and a minimum resistance and the resistance value of the first deformation resistor 502 is negatively correlated to the bending angle of the foldable display 100. The current folding angle of the foldable display 100 can be determined by comparing the magnitude of the voltage signal detected by the processor 504.

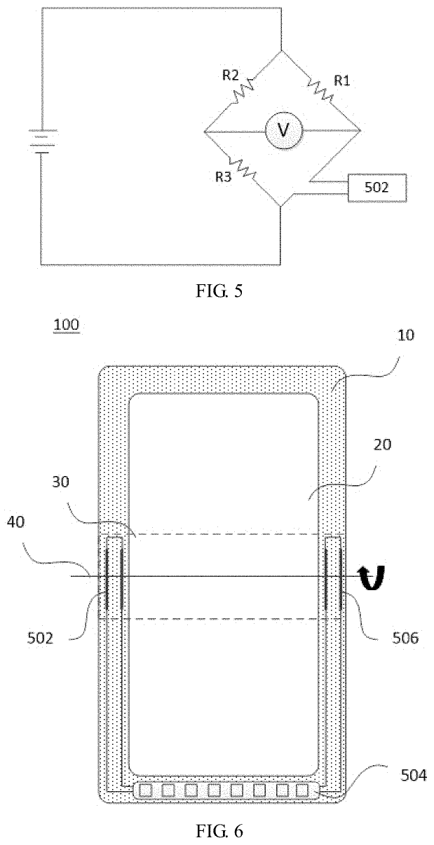

FIG. 6 is a schematic diagram of a foldable display provided with a pressure sensor according to Embodiment 2 of the present application. Wherein the resistive pressure sensor further includes a second deformation resistor 506, the second deformation resistor 506 is located in the non-visible area 20 of the display surface of the foldable display 100 and corresponding to a position of the first deformation resistor 502.

In Embodiment 2, the resistive pressure sensor further includes a fourth resistor, a fifth resistor, and a sixth resistor, the fourth resistor, the fifth resistor and the sixth resistor are balance resistors each having a constant resistance, and the constant resistance of each of the fourth, fifth and sixth resistors is equal to a resistance of the second deformation resistor when the second deformation resistor is not deformed. The fourth resistor, the fifth resistor, the sixth resistor and the second deformation resistor constitute a second Wheatstone balanced bridge.

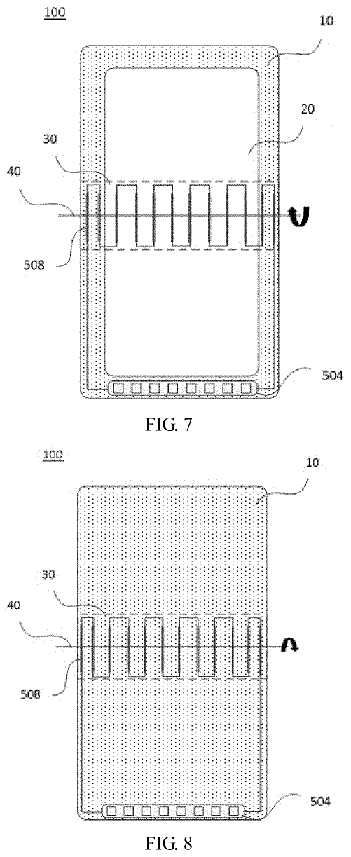

Referring to FIG. 7, FIG. 7 is a schematic diagram of a foldable display provided with a pressure sensor according to Embodiment 3 of the present application. Wherein the first Wheatstone balance bridge is located on the non-display surface of the foldable display 100, the resistors constituting the first Wheatstone balanced bridge are made of transparent material, geometric centers of the first deformation resistors 508 overlap with a bending axis 40 of the bendable region 30, and a projection length of the first deformation resistor 508 along the bending axis 40 direction of the bendable region is equal to a length of the bending axis 40 of the bendable region 30.

In this embodiment, the number of the first deformation resistors 508 is much larger than the number of the first deformation resistors 502 in Embodiment 1 and Embodiment 2. The variation range of the resistance of the first deformation resistors 508 in this embodiment is also much larger than the deformation resistance 502 in the foregoing embodiments. Therefore, this embodiment can measure the deformation angle of the display 100 more accurately.

Referring to FIG. 8, FIG. 8 shows Embodiment 4 of the present application. Unlike Embodiment 3, in Embodiment 4, the first Wheatstone balance bridge is located on a non-display surface of the foldable display 100. Similarly, the geometric centers of the first deformation resistors 508 overlaps with the bending axis 40 of the bendable region 30, projection length of the first deformation resistors 508 in the direction of the bending axis 40 of the bendable region 30 is equal to the length of the bending axis 40 of the bendable region 30. The deformation angle of the display 100 can be measured more accurately.

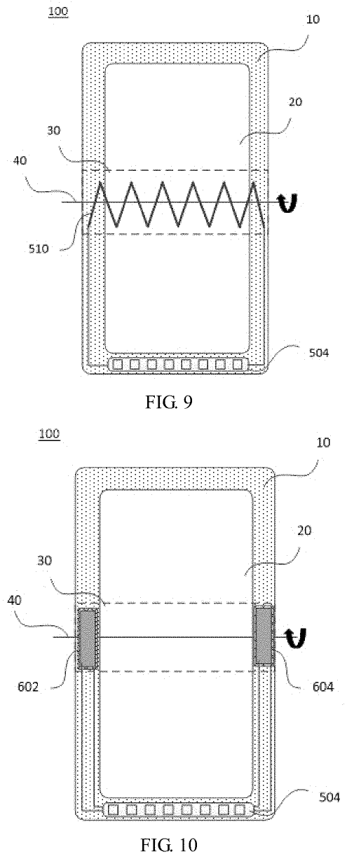

Referring to FIG. 9, FIG. 9 shows Embodiment 5 of the present application, wherein unlike Embodiments 3 and 4, the first deformation resistors 510 have a triangular-shaped polygonal line distribution instead of a rectangular polygonal line. In practice, the first deformation resistors 510 can take a variety of different arrangements depending on its material and properties. In addition to the above-described embodiments, various shapes such as a sinusoidal arrangement, a shock wave arrangement and the like can also be used. Details are not described herein again.

Referring to FIG. 10, FIG. 10 shows Embodiment 6 of the present application, wherein the pressure sensor is a capacitive pressure sensor. The capacitive pressure sensor includes a deformation capacitor. In this embodiment, the capacitive pressure sensor includes a first deformation capacitor 602 and a second deformation capacitor 604. The first deformation capacitor 602 and the second deformation capacitance 604 are respectively located in the non-visible area 10 on both sides of the visible area 20 of the display surface the foldable display 100. The geometric centers of the first deformation capacitor 602 and the second deformation capacitor 604 overlaps with a bending axis 40 of the bendable region, two plates of the first deformation capacitor 602 and the second deformation capacitor 604 are conductive layers printed on both sides of an organic elastic insulator respectively.

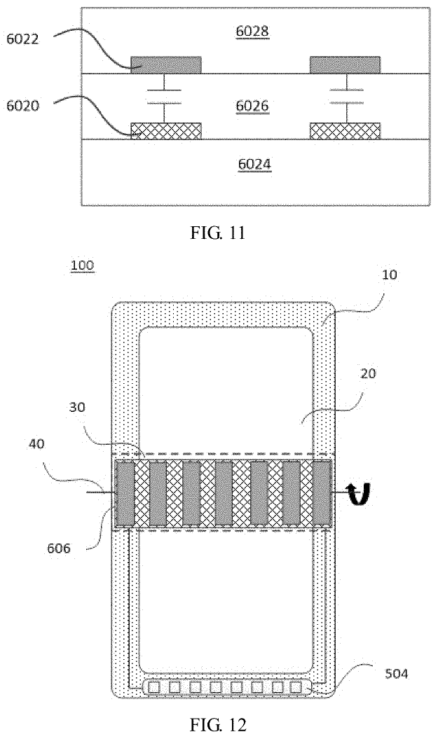

Referring to FIG. 11, FIG. 11 is a schematic diagram of a principle of the pressure sensor of FIG. 10. The foldable display 100 includes a substrate 6024, a first insulating layer 6026, and a second insulating layer 6028. The first deformation capacitor 602 includes a first plate 6022 and a second plate 6020. The material of the first plate 6022 and the second plate 6020 can be a metal such as TiAlTi Mesh, Pt, AgNW and the like, they can also be a non-metallic material such as a high-resistance carbon paste, a graphene film, a carbon nanotube, an organic conductive material and the like. The manufacturing process of the first deformation capacitor 602 and the second deformation capacitor 604 includes a yellow light process, a laser etching process, a printing process and the like.

When the foldable display 100 is in the unfolded state, the deformation capacitor has a minimum capacitance value, and the electrical signal detected by the processor 504 is a minimum voltage signal. When the foldable display 100 is in the folded state, the deformation capacitor has a maximum capacitance value, and the electrical signal detected by the processor 504 is a maximum voltage signal. The current state of position of the foldable display 100 can be determined by comparing the magnitude of the voltage signal detected by the processor 504.

When the foldable display 100 is in the half-folded state, a capacitance value of the first deformation capacitance is between the maximum capacitance and the minimum capacitance and the capacitance value of the first deformation capacitance is negatively correlated to the bending angle of the foldable display, the current folding angle of the foldable display 100 can be determined by comparing the magnitude of the voltage signal detected by the processor 504.

Referring to FIG. 12, FIG. 12 shows Embodiment 7 of the present application. In order to obtain the bending angle of the foldable display 100 accurately, the pressure sensor is required to provide a finer electrical signal, therefore, it is necessary to increase the area of the capacitive pressure sensor. In this embodiment, the deformation capacitor 606 has a length equal to the length of the bendable region 30 and covering the visible area 20 and the non-visible area 10. In order not to affect the display effect, the deformation capacitor 606 is a transparent material. Of course, the variable capacitor 606 can also be located on the non-display surface of the foldable display 100. In this case, the capacitive pressure sensor is not required to be a transparent material.

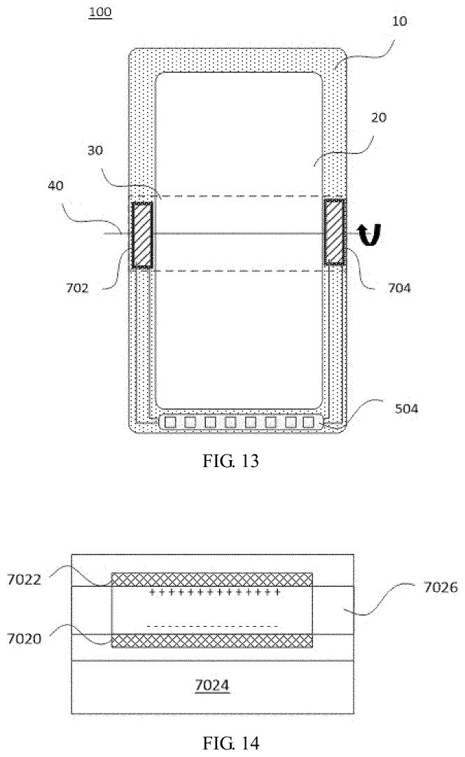

Referring to FIG. 13, FIG. 13 shows Embodiment 8 of the present application, the pressure sensor is a piezoelectric pressure sensor, the piezoelectric pressure sensor includes a piezoelectric film 704. The piezoelectric film 704 includes a first surface, a second surface, a first electrode 7022 electrically connected to the first surface of the piezoelectric film 704 and a second electrode 7020 electrically connected to the second surface of the piezoelectric film 704, the first electrode 7022 is in close contact with the bendable region 30 and the second electrode 7020 is away from the bendable region 30.

The material of the piezoelectric film 7040 can be a metal such as TiAlTi Mesh, Pt, AgNW and the like, they can also be a non-metallic material such as a high-resistance carbon paste, a graphene film, a carbon nanotube, an organic conductive material and the like. The manufacturing process of the piezoelectric film 704 includes a yellow light process, a laser etching process, a printing process and the like.

When the foldable display 100 is in the unfolded state, the first surface and the second surface are not deformed, and the surface stress is zero, a minimum voltage difference exits between the first electrode and the second electrode, wherein the electrical signal detected by the processor 504 is a minimum piezoelectric signal.

When the foldable display 100 is in the folded state, a resultant force of the first surface is in a direction of the bending radius, perpendicular to the bending axis 40 of the bendable region and pointing to the outside of a bending arc. An absolute value of a resultant force generated by a compressive stress of the second surface is greater than an absolute value of the resultant force generated by a compressive stress of the first surface, a direction of the resultant force generated by the second surface is opposite to the direction of the resultant force generated by the first surface. A pressure applied to a surface of the piezoelectric film is a sum of the compressive stresses of the first surface and the compressive stresses of the second surface, a direction of the pressure applied to a surface of the piezoelectric film is consistent with the direction of the compressive stress of the second surface. Electric charges inside the piezoelectric film is shifted by the pressure, positive and negative charges are collected on the first surface and the second surface of the piezoelectric film respectively, and the electrical signal detected by the processor 504 is the maximum piezoelectric signal.

When the foldable display 100 is in the half-folded state, a magnitude of the piezoelectric signal between the first surface and the second surface of the piezoelectric film is between the maximum piezoelectric signal and the minimum piezoelectric signal, a piezoelectric signal of the piezoelectric film is positively correlated with a bending angle of the foldable display. The current folding angle of the foldable display can be determined by comparing the magnitude of the voltage signal detected by the processor 504.

The present application provides a pressure sensor on a bending axis of a bending region of a foldable display, therefore a change of the bending state of the bending axis of the bending region can be converted into a change of an electric signal by the pressure sensor to complete the detection of the bending state of the display screen. This method does not need to rely on external optical signals or magnetic signals and is completely completed by the deformation of the display itself when bending. The foldable display screen of the present application can completely eliminate the interference of external factors on the detection result and greatly improve the accuracy of detection and avoiding misjudgment.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. A foldable display, comprising:
a bendable region, the bendable region comprising a first surface functioning as a display surface of the display and a second surface disposed opposite to the first surface;
wherein the foldable display has an unfolded state, a folded state, and a half-folded state;
wherein the foldable display comprises a state detecting unit for detecting a current state of the foldable display, the state detecting unit comprises a pressure sensor disposed in the bendable region for detecting a deformation state of a surface of the bendable region and generating an electrical signal indicating a corresponding deformed state.

2. The foldable display according to claim 1, wherein in the unfolded state, the first surface and the second surface are not deformed;
wherein in the folded state, the first surface and the second surface are deformed, and an included angle between portions of the display on both sides of the bendable region is 0 degrees; and
wherein in the half-folded state, the first surface and the second surface are deformed, and the included angle between the portions of the display on both sides of the bendable region is greater than 0 degrees and less than 180 degrees.

3. The foldable display according to claim 1, wherein the state detecting unit further comprises a processor configured to receive and identify the electrical signal transmitted by the pressure sensor, the processor is used for obtaining the angle between the portions of the display on both sides of the bendable region according to the electrical signal and indicating a state in which the foldable display is in.

4. The foldable display according to claim 1, wherein a display surface of the foldable display comprises a visible area and a non-visible area located beside or around the visible area, and the pressure sensor is located on the non-visible area of the display surface or on a non-display surface of the foldable display.

5. The foldable display according to claim 4, wherein the display surface of the foldable display comprises a visible area and a non-visible area located beside or around the visible area, and the pressure sensor is located in the visible area of the display surface of the foldable display and the pressure sensor is made of transparent material.

6. The foldable display according to claim 5, wherein the pressure sensor is a resistive pressure sensor.

7. The foldable display according to claim 6, wherein the resistive pressure sensor comprises a first deformation resistor.

8. The foldable display according to claim 7, wherein the resistive pressure sensor further comprises a first resistor, a second resistor, and a third resistor; the first resistor, the second resistor and the third resistor are balanced resistors each having a constant resistance, and the constant resistance is equal to a resistance of the first deformation resistor when the first deformation resistor is not deformed;
wherein the first resistor, the second resistor, the third resistor and the first deformation resistor constitute a first Wheatstone balance bridge.

9. The foldable display according to claim 8, wherein the first Wheatstone balance bridge is located in the non-visible area of the display surface of the foldable display, and a geometric center of the first deformation resistor overlaps with a bending axis of the bendable region.

10. The foldable display according to claim 9, wherein the resistive pressure sensor further comprises a second deformation resistor, the second deformation resistor is located in the non-visible area of the display surface of the foldable display and corresponding to a position of the first deformation resistor;
wherein the resistive pressure sensor further comprises a fourth resistor, a fifth resistor, and a sixth resistor; the fourth resistor, the fifth resistor and the sixth resistor are balance resistors each having a constant resistance, and the constant resistance of each of the fourth, fifth and sixth resistors is equal to a resistance of the second deformation resistor when the second deformation resistor is not deformed;
wherein the fourth resistor, the fifth resistor, the sixth resistor and the second deformation resistor constitute a second Wheatstone balanced bridge.

11. The foldable display according to claim 8, wherein the first Wheatstone balance bridge is located on the non-display surface of the foldable display, a geometric center of the first deformation resistor overlaps with a bending axis of the bendable region, and a projection length of the first deformation resistor along the bending axis direction of the bendable region is equal to a length of the bending axis of the bendable region.

12. The foldable display according to claim 8 wherein the first Wheatstone balance bridge is located on a display surface of the foldable display and the resistors constituting the first Wheatstone balanced bridge each are made of transparent material, a geometric center of the first deformation resistor overlaps with a bending axis of the bendable region, a projection length of the first deformation resistor along the bending axis direction of the bendable region is equal to a length of the bending axis of the bendable region.

13. The foldable display according to claim 7, wherein when the foldable display is in the unfolded state, the first deformation resistor has a maximum resistance value and the electrical signal detected by the processor is a maximum voltage signal;
wherein when the foldable display is in the folded state, the first deformation resistor has a minimum resistance value and the electrical signal detected by the processor is a minimum voltage signal; and
wherein the current state of position of the foldable display can be determined by comparing the magnitude of the voltage signal detected by the processor.

14. The foldable display according to claim 7, wherein when the foldable display is in the half-folded state, a resistance value of the first deformation resistor is between a maximum resistance and a minimum resistance and the resistance value of the first deformation resistor is negatively correlated to the bending angle of the foldable display;
wherein the current folding angle of the foldable display can be determined by comparing the magnitude of the voltage signal detected by the processor.

15. The foldable display according to claim 5, wherein the pressure sensor is a capacitive pressure sensor.

16. The foldable display according to claim 15 wherein the capacitive pressure sensor comprises a deformation capacitance.

17. The foldable display according to claim 16, wherein a geometric center of the deformation capacitor overlaps with a bending axis of the bendable region, two plates of the deformation capacitor are conductive layers printed on both sides of an organic elastic insulator respectively.

18. The foldable display of claim 17, wherein when the foldable display is in the unfolded state, the deformation capacitor has a minimum capacitance value, and the electrical signal detected by the processor is a minimum voltage signal;
wherein when the foldable display is in the folded state, the deformation capacitor has a maximum capacitance value, and the electrical signal detected by the processor is a maximum voltage signal; and
wherein the current state of position of the foldable display can be determined by comparing the magnitude of the voltage signal detected by the processor.

19. The foldable display according to claim 18, wherein when the foldable display is in the half-folded state, a capacitance value of the first deformation capacitance is between the maximum capacitance and the minimum capacitance and the capacitance value of the first deformation capacitance is negatively correlated to the bending angle of the foldable display;
wherein the current folding angle of the foldable display can be determined by comparing the magnitude of the voltage signal detected by the processor.

20. The foldable display according to claim 5, wherein the pressure sensor is a piezoelectric pressure sensor.

21.-24. (canceled)
